(19) United States
(12) Patent Application Publication
(10) Pub. No.: US 2014/0064901 A1
(43) Pub. Date: Mar. 6, 2014

(54) TRANSPORTING DEVICE

(71) Applicants: HON HAI PRECISION INDUSTRY CO., LTD., New Taipei (TW); HONG FU JIN PRECISION INDUSTRY (ShenZhen)CO., LTD., Shenzhen (CN)

(72) Inventor: BO LONG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/953,918

(22) Filed: Jul. 30, 2013

(30) Foreign Application Priority Data
Aug. 31, 2012 (CN) 2012103177127

(51) Int. Cl. H01L 21/677

(52) U.S. Cl. CPC H01L 21/67766
USPC 414/744.5

(57) ABSTRACT

A transporting device includes a base, a driving assembly, a first linking mechanism, and a second linking mechanism. The first linking mechanism includes first and second connecting links that re hinged together. The second linking mechanism includes third and fourth connecting links that are hinged together. The first and the third connecting links are rotatably driven by the driving assembly, such that the first linking mechanism and the second linking mechanism are movable relative to the base toward each other, away from each other, or in a same direction, for transporting a workpiece.

### BACKGROUND

1. Technical Field

The present disclosure relates to transporting devices, and particularly to a transporting device employed in a robot arm.

2. Description of the Related Art

In a manufacturing process, a transporting device can be mounted on a robot arm for transporting workpieces. The transporting device includes a driver and a connection shaft. One end of the connection shaft is securely mounted on a distal end of the robot arm. A clamping member is mounted on the other end of the connection shaft for clamping the workpieces. The driver is mounted on the connection shaft for driving the clamping member to clamp the workpieces. The driver moves with the connection shaft, which adds weight to the connection shaft, such that the connection shaft driven by the robot arm moves slowly. In addition, the single connection shaft has a weak structure, which results in a short usage lifetime or lifespan of the transporting device.

Therefore, there is room for improvement within the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout several views.

FIG. 1 is an assembled, isometric view of one embodiment of a transporting device.

FIG. 2 is an exploded, isometric view of the transporting device of FIG. 1.

FIG. 3 is similar to FIG. 2, but viewed from another aspect.

FIG. 4 is a cross-sectional view of the transporting device, taken along line IV-IV of FIG. 1.

FIG. 5 is a partial, cross-sectional view of the transporting device, taken along line V-V of FIG. 1.

### DETAILED DESCRIPTION

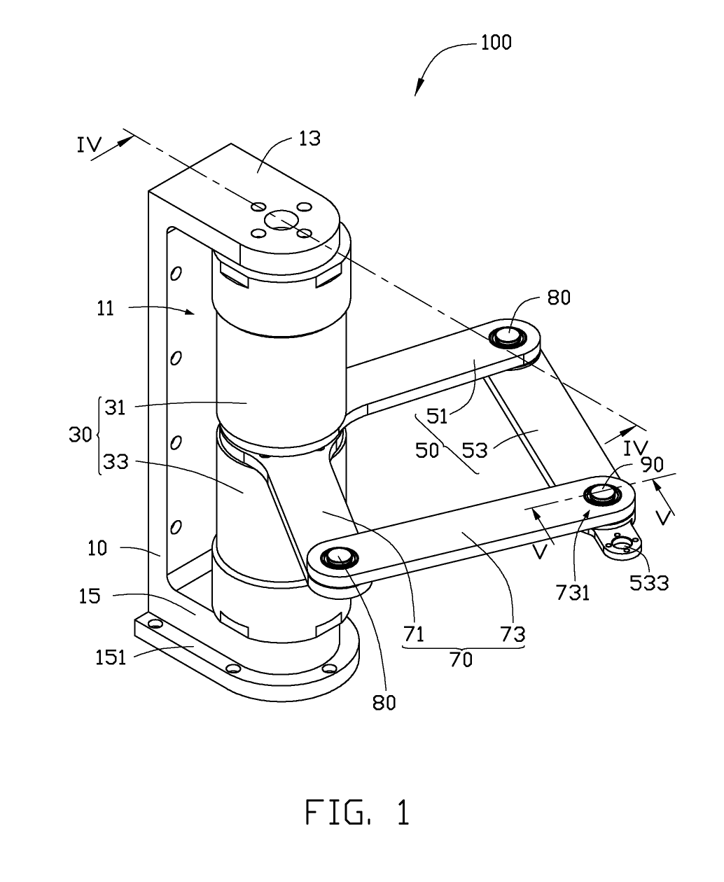

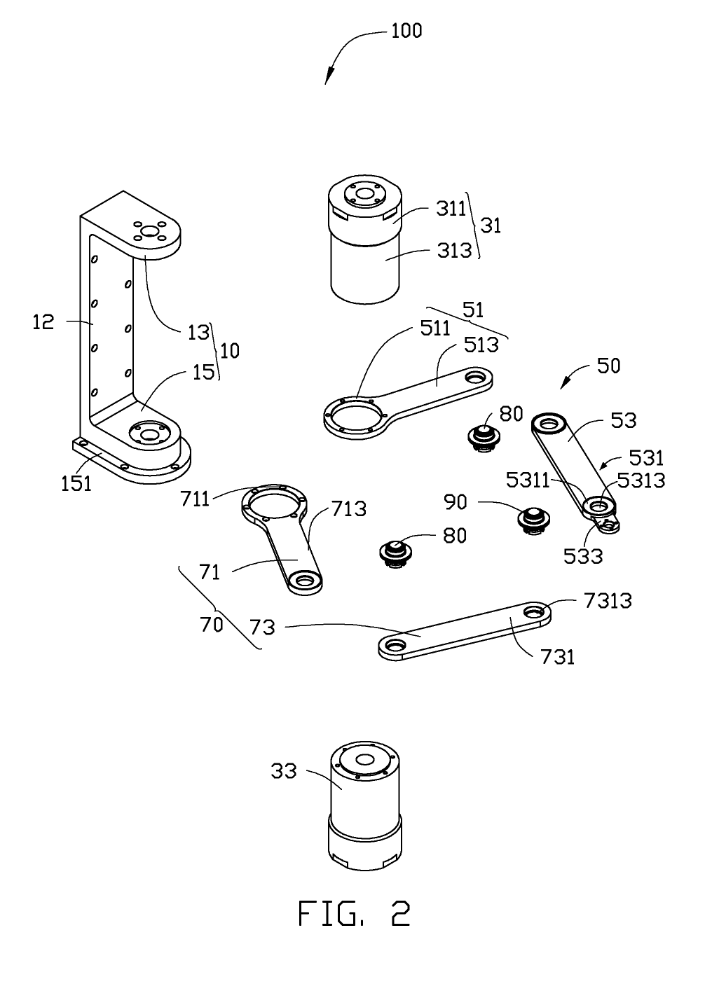

FIGS. 1 and 2 show an embodiment of a transporting device 100 connected to a robot arm (not shown) for transporting workpieces (not shown). The transporting device 100 includes a base 10, a driving assembly 30, a first linking mechanism 50, a second linking mechanism 70, two first hinge assembles 80, and a second hinge assembly 90. The driving assembly 30 is mounted on the base 10. The first linking mechanism 50 and the second linking mechanism 70 are securely connected to the driving assembly 30, and are hinged together by the hinge assembly 90.

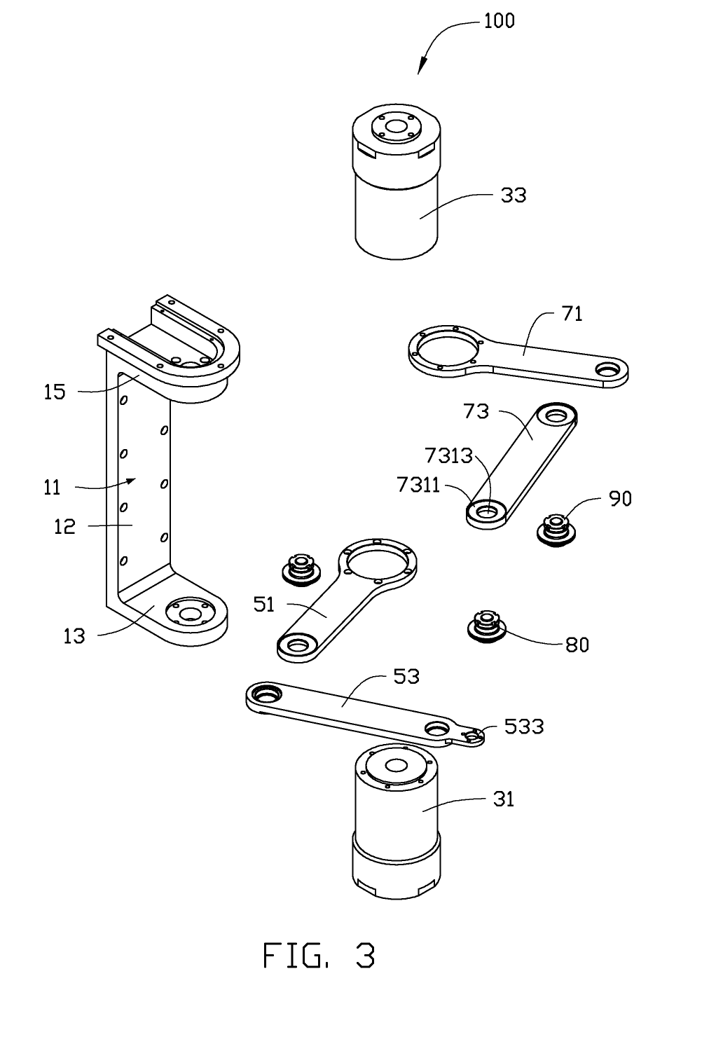

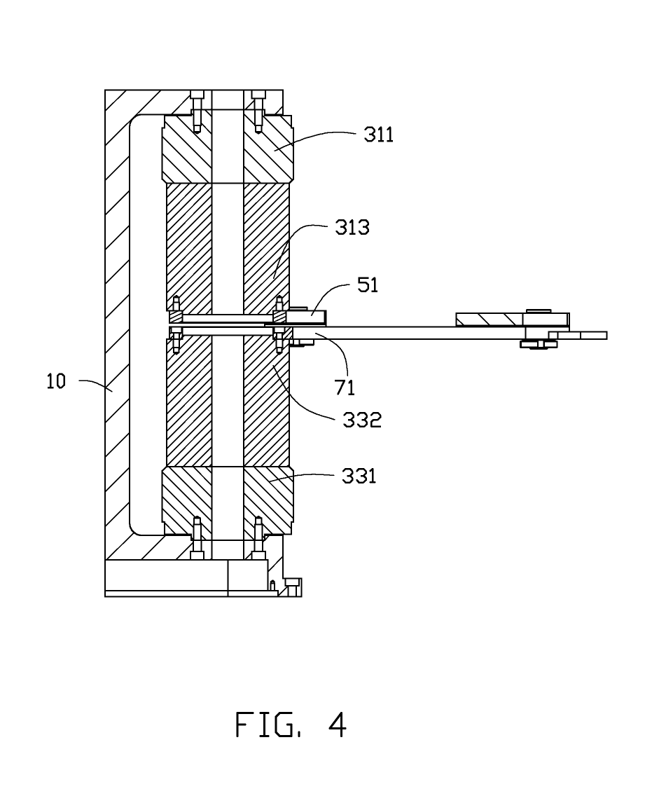

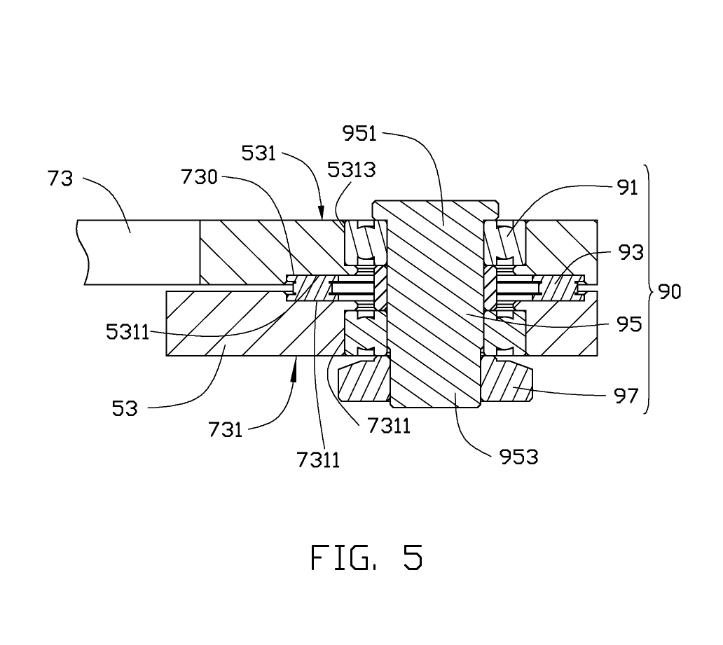

FIGS. 3 through 5 show the transporting device 100 in detail. The base 10 is connected to a distal end of the robot arm. The base 10 includes a main portion 12, a first mounting portion 13, and a second mounting portion 15. The main portion 12 is a plate-like piece. The first mounting portion 13 extends substantially perpendicularly from one end of the main portion 12. The second mounting portion 15 extends substantially perpendicularly from the other end of the main portion 12. Both the first mounting portion 13 and the second mounting portion 15 extend along a substantially same direction, such that the main portion 12, the first mounting portion 13, and the second mounting portion 15 cooperatively form a U-shaped structure defining a receiving space 11 for receiving the driving assembly 30. A connecting portion 151 is attached on a surface of the second mounting portion 15 away from the first mounting portion 13. The connecting portion 151 is securely connected to a distal end of the robot arm.

The driving assembly 30 includes a first driving member 31 and a second driving member 33, which are controlled by a controller (not shown). The first driving member 31 includes a main body 311 and a driving end 313 rotatably connected to and driven by the main body 311. The main body 311 is mounted to the first mounting portion 13. The driving end 313 is located away from the first mounting portion 13. The second driving member 33 includes a main body 331 and a driving end 332 rotatably connected to and driven by the main body 331. The main body 331 is mounted to the second mounting portion 15. The main body 311 of the first driving member 31 and the main body 331 of the second driving member 33 are substantially coaxial. The driving end 332 of the second driving member 33 is positioned adjacent to the driving end 313 of the first driving member 31. In an illustrated embodiment, the first driving member 31 and the second driving member 33 are direct drive motors.

The first linking mechanism 50 is securely connected to the driving end 313, such that the first linking mechanism 50 is driven to rotate relative to the base 10 by the first driving member 31. The first linking mechanism 50 includes a first connecting link 51 and a second connecting link 53 hinged to the first connecting link 51. The first connecting link 51 includes a connecting portion 511 and a pushing portion 513 extending from the connecting portion 513. The connecting portion 511 is securely mounted to an end of the driving end 313. The pushing portion 513 is strip-like. A free end of the pushing portion 513 is hinged to one end of the second connecting link 53 by one first hinge assembly 80. The second connecting link 53 is strip-like. The second connecting link 53 includes a hinged end 531 away from the pushing portion 513. The hinged end 531 defines a receiving groove 5311. A hinged hole 5313 is defined in a bottom of the receiving groove 5311. A mounting arm 533 is formed on the hinged end 531. A clamping member (not shown) is mounted on the mounting arm 533 for clamping the workpieces.

The second linking mechanism 70 is similar to the first linking mechanism 50. The second linking mechanism 70 is securely connected to the driving end 332, such that the second linking mechanism 70 is driven by the second driving member 33 to move rotatively relative to the base 10. The second linking mechanism 70 includes a third connecting link 71 and a fourth connecting link 73 hinged to the third connecting link 71. A connecting portion 711 of the third connecting link 71 is securely connected to the driving end 332. A pushing portion 713 of the third connecting link 71 is hinged to the fourth connecting link 73. In the illustrated embodiment, the third connecting link 71 is hinged to the fourth connecting link 73 by the other one first hinge assembly 80. The fourth connecting link 73 includes a hinged end 731 away from the third connecting link 71. The hinged end 731 is hinged to the hinged end 531 of the first linking mechanism 50. A receiving groove 7311 is defined in the hinged end 731 corresponding to the receiving groove 5311 of the first linking mechanism 50. A hinged hole 7313 is defined in a bottom of the receiving groove 7311 of the hinged end 731. The receiving grooves 7311, 5311 cooperatively define a mounting space 730, and the hinged holes 7313, 5313 are coaxial.

The first hinge assembly 80 has a same structure as the second hinge assembly 90. For simplicity, only the second hinge assembly 90 is described in detail. The second hinge assembly 90 includes two first bearings 91, a second bearing 93, a connecting member 95, and a locking member 97. The two first bearings 91 are respectively received in the hinged holes 5313, 7313. The second bearing 93 is received in the mounting space 730 and resists against the hinged end 531 and the hinged end 731, such that the fourth connecting link 73 is movable relative to the second connecting link 53. The connecting member 95 includes a block portion 951 and a locking portion 953 formed on the block portion 951. The block portion 951 is plate-like and resists against an inner periphery of one first bearing 91 mounted on the hinged end 531 of the first linking mechanism 50. The locking portion 953 is substantially cylindrical. One end of the locking portion 953 away from the first linking mechanism 50 passes through the first bearing 91 mounted on the hinged end 531, the second bearing 93, and the other first bearing 91 mounted on the hinged end 731 in that order, and then partly protrudes out from the hinged end 731. The locking member 97 is threadedly engaged with the locking portion 953, and resists against the other first bearing 91 mounted on the hinged end 731, such that a distance between the second connecting link 53 and the fourth connecting link 73 is adjustable by rotation of the connecting member 95 and the locking member 97.

In assembly, the first driving member 31 and the second driving member 33 are mounted to the first mounting portion 13 and the second mounting portion 15, respectively. The hinged end 531 of the first linking mechanism 50 and the hinged end 731 of the second linking mechanism 70 are assembled together, and the second bearing 93 is placed in the mounting space 730. The two first bearings 91 are placed on the hinged end 531 and the hinged end 731, respectively. One end of the locking portion 953 passes through the first bearing 91 mounted on the hinged end 531, the second bearing 93, and the other first bearing 91 mounted on the hinged end 731 in that order, and then is threaded with the locking member 97. The first connecting link 51 and the third connecting link 71 are respectively mounted on the first driving member 31 and the second driving member 33, and the clamping member is mounted on the mounting arm 533.

In use, the workpiece is clamped by the clamping member. The first driving member 31 and the second driving member 33 drive the first linking mechanism 50 and the second linking mechanism 70, respectively, such that the first linking mechanism 50 and the second linking mechanism 70 move toward each other, away from each other, or in a same direction. When the driving end 313 rotates clockwise, and the driving end 332 rotates counterclockwise, the first linking mechanism 50 and the second linking mechanism 70 move toward each other, and the first connecting link 51 and the third connecting link 71 respectively move the second connecting link 53 and the fourth connecting link 73 away from the main portion 12 of the base 10. When the driving end 313 rotates counterclockwise, and the driving end 332 rotates clockwise, the first linking mechanism 50 and the second linking mechanism 70 move away from each other, and the first connecting link 51 and the third connecting link 71 respectively move the second connecting link 53 and the fourth connecting link 73 toward the main portion 12 of the base 10. That is to say, when the first connecting link 51 and the third connecting link 71 move toward or away from each other, the second connecting link 53 and the fourth connecting link 73 telescopes relative to the base 10. When the driving end 313 and the driving end 332 rotate in a same direction relative to the base 10, the first linking mechanism 50 and the second linking mechanism 70 rotate in the same direction relative to the base 10, and the second connecting link 53 and the fourth connecting link 73 rotate with the first connecting link 51 and the third connecting link 71 in the same direction relative to the base 10.

The driving assembly 30 moves the first linking mechanism 50 and the second linking mechanism 70 by a single joint formed between the connecting portion 511 and the connecting portion 711, such that no extra force is added to the first linking mechanism 50 and the second linking mechanism 70. Thus, the first linking mechanism 50 and the second linking mechanism 70 move swiftly. In addition, the transporting device 100 has two linking mechanisms instead of one. Thus, the transporting device 100 is sturdier.

In other embodiments, if the workpieces are suitable for hanging on the mounting arm 533, the clamping member can be omitted. The main body 311 of the first driving member 31 and the main body 331 of the second driving member 33 can be non-coaxial, and lengths of the first linking mechanism 50 and the second linking mechanism 70 can be changed accordingly. The first bearings 91 and the second bearing 93 can be omitted, as long as the hinged ends 731, 531 are smooth enough to rotate swiftly, such that the hinged ends 731, 531 are hinged together by the connecting member 95 and the locking member 97.

It is to be understood, however, that even through numerous characteristics and advantages of the disclosure have been set forth in the foregoing description, together with details of the structure and function of the embodiments, the disclosure is illustrative only, and changes may be made in detail, especially in the matters of shape, size, and arrangement of parts within the principles of the embodiments to the full extent indicated by the broad general meaning of the terms in which the appended claims are expressed.

What is claimed is:

1. A transporting device, comprising:
a base;
a driving assembly comprising a first driving member and a second driving member, the first driving member and the second driving member securely mounted on the base;
a first linking mechanism comprising a first connecting link and a second connecting link hinged to the first connecting link, the first connecting link securely connected to the first driving member, a mounting arm formed on one end of the second connecting link away from the first connecting link for loading a workpiece; and
a second linking mechanism comprising a third connecting link and a fourth connecting link hinged to the third connecting link, the third connecting link securely connected to the second driving member, one end of the fourth connecting link away from the third connecting link hinged to the end of the second connecting link away from the first connecting link, wherein the first connecting link and the third connecting link are rotatable driven by the first driving member and the second driving member, such that the first linking mechanism and the second linking mechanism are movable toward each other or away from each other to enable the first linking mechanism and the second linking mechanism telescope, or the first linking mechanism and the second linking mechanism are movable in a same direction to enable the first linking mechanism and the second linking mechanism rotate in the same direction relative to the base, for transporting the workpiece.

2. The transporting device of claim 1, wherein the second connecting link comprises a hinged end away from the first connecting link, the fourth connecting link comprises a hinged end away from the third connecting link, the transporting device further comprises a hinge assembly, the hinged end of the second connecting link is hinged to the hinged end of the fourth connecting link by the hinge assembly.

3. The transporting device of claim 2, wherein a hinge hole is defined in the hinged end of the second connecting link, a hinged hole is defined in the hinged end of the fourth connecting link corresponding to the hinged hole of the second connecting link, the hinge assembly comprises a connecting member and a locking member threaded with the connecting member, one end of the connecting member passes through the hinged holes of the second connecting link and the fourth connecting link, and then is threaded with the locking member.

4. The transporting device of claim 3, wherein a receiving groove is defined in the hinged end of the second connecting link around a periphery of the hinged hole of the second connecting link, a receiving groove is defined in the hinged end of the fourth connecting link around a periphery of the hinged hole of the fourth connecting link, the receiving grooves of the second connecting link and the fourth connecting link cooperatively define a mounting space, the hinge assembly further comprises two first bearings and a second bearing, the two first bearings are respectively placed in the receiving grooves of the second connecting link and the fourth connecting link, the second bearing is placed in the mounting space between the two first bearings, and resists against the hinged ends of the second connecting link and the fourth connecting link, respectively, the locking portion passes through the two first bearings and the second bearing, and is threaded with the locking member.

5. The transporting device of claim 4, wherein the connecting member comprises a block portion and a locking portion formed on the block portion, the block portion resists against one of the two first bearings mounted on the first linking mechanism, one end of the locking portion passes through the two first bearings and the second bearing, and is threaded with the locking member, the locking member resists against the other one of the two first bearings mounted on the second linking mechanism, such that a distance between the second connecting link and the fourth connecting link is adjustable.

6. The transporting device of claim 1, wherein the base comprises a main portion, a first mounting portion, and a second mounting portion, each of the first driving member and the second driving member comprises a main body and a driving end rotatably connected to and driven by the main body, the main body of the first driving member is securely mounted on the first mounting portion, the main body of the second driving member is securely mounted on the second mounting portion, the driving end of the second driving member is positioned adjacent to the driving end of the first driving member, and is connected to the end of the fourth connecting link away from the third connecting link.

7. The transporting device of claim 6, wherein the first connecting link comprises a connecting portion and a pushing portion extending from the connecting portion, the connecting portion is securely mounted on the driving end of the first driving member, a free end of the pushing portion is hinged to the second connecting link.

8. The transporting device of claim 1, wherein the first driving member and the second driving member are coaxial.

9. A transporting device, comprising:
a base;
a driving assembly comprising a first driving member and a second driving member, the first driving member and the second driving member being securely mounted on the base and coaxial;
a first linking mechanism comprising a first connecting link and a second connecting link hinged to the first connecting link, the first connecting link securely connected to the first driving member, a mounting arm for loading a workpiece formed on one end of the second connecting link away from the first connecting link, the second connecting link comprising a hinged end away from the first connecting link;
a second linking mechanism comprising a third connecting link and a fourth connecting link hinged to the third connecting link, the third connecting link securely connected to the second driving member, the fourth connecting link comprising a hinged away from the first connecting link; and
a hinge assembly, wherein the hinged end of the fourth connecting link is hinged to the hinged end of the second connecting link by the hinge assembly, the first connecting link and the third connecting link are rotatable driven by the first driving member and the second driving member, such that the first linking mechanism and the second linking mechanism are movable relative to the base toward each other, away from each other, or in a same direction, for transporting the workpiece.

10. The transporting device of claim 9 wherein a hinge hole is defined in the hinged end of the second connecting link, a hinged hole is defined in the hinged end of the fourth connecting link corresponding to the hinged hole of the second connecting link, the hinge assembly comprises a connecting member and a locking member threaded with the connecting member, one end of the connecting member passes through the hinged holes of the second connecting link and the fourth connecting link, and then is threaded with the locking member.

11. The transporting device of claim 10, wherein a receiving groove is defined in the hinged end of the second connecting link around a periphery of the hinged hole of the second connecting link, a receiving groove is defined in the hinged end of the fourth connecting link around a periphery of the hinged hole of the fourth connecting link, the receiving grooves of the second connecting link and the fourth connecting link cooperatively define a mounting space, the hinge assembly further comprises two first bearings and a second bearing, the two first bearings are respectively placed in the receiving grooves of the second connecting link and the fourth connecting link, the second bearing is placed in the mounting space between the two first bearings, and resists against the hinged ends of the second connecting link and the fourth connecting link, respectively, the locking portion passes through the two first bearings and the second bearing, and is threaded with the locking member.

12. The transporting device of claim 11, wherein the connecting member comprises a block portion and a locking portion formed on the block portion, the block portion resists against one of the two first bearings mounted on the first linking mechanism, one end of the locking portion passes through the two first bearings and the second bearing, and is threaded with the locking member, the locking member resists against the other one of the two first bearings mounted on the second linking mechanism, such that a distance between the second connecting link and the fourth connecting link is adjustable.

13. The transporting device of claim 9, wherein the base comprises a main portion, a first mounting portion, and a second mounting portion, each of the first driving member and the second driving member comprises a main body and a driving end rotatably connected to and driven by the main body, the main body of the first driving member is securely mounted on the first mounting portion, the main body of the second driving member is securely mounted on the second mounting portion, the driving end of the second driving member is positioned adjacent to the driving end of the first driving member, and is connected to the end of the fourth connecting link away from the third connecting link.

14. The transporting device of claim 13, wherein the first connecting link comprises a connecting portion and a pushing portion extending from the connecting portion, the connecting portion is securely mounted on the driving end of the first driving member, a free end of the pushing portion is hinged to the second connecting link.
